(19) United States
(12) Patent Application Publication
(10) Pub. No.: US 2025/0006625 A1
(43) Pub. Date: Jan. 2, 2025

(54) SEMICONDUCTOR PACKAGE

(71) Applicant: SAMSUNG ELECTRONICS CO., LTD., Suwon-si (KR)

(72) Inventors: Hyunsoo CHUNG, Suwon-si (KR); Kwang-Soo Kim, Suwon-si (KR); Jaesic Lee, Suwon-si (KR)

(21) Appl. No.: 18/437,638

(22) Filed: Feb. 9, 2024

(30) Foreign Application Priority Data
Jun. 28, 2023 (KR) 10-2023-0083696

(51) Int. Cl. H01L 23/522; H01L 23/00; H01L 23/31; H01L 23/48; H01L 23/498; H01L 23/538; H01L 25/065; H10B 80/00

(52) U.S. Cl. CPC H01L 23/5222; H01L 23/3128; H01L 23/481; H01L 23/5226; H01L 23/5385; H01L 25/0652; H10B 80/00; H01L 23/49816; H01L 24/16; H01L 24/32; H01L 24/73; H01L 2224/16145; H01L 2224/16227; H01L 2224/32225; H01L 2224/73204

(57) ABSTRACT

A semiconductor package is provided. The semiconductor package includes a first semiconductor chip, which includes: a first semiconductor substrate having a first surface and a second surface, which are opposite to each other; a circuit layer on the first surface; a first interconnection layer on the circuit layer; a second interconnection layer on the second surface; a penetration via extending from the second surface into the first semiconductor substrate; and a capacitor extending from the second surface toward the first surface. The capacitor is spaced apart from the penetration via in a first direction that is parallel to the first surface of the first semiconductor substrate.

### CROSS-REFERENCE TO RELATED APPLICATION

This application claims priority to Korean Patent Application No. 10-2023-0083696, filed on Jun. 28, 2023, in the Korean Intellectual Property Office, the disclosure of which is incorporated by reference herein in its entirety.

### BACKGROUND

The present disclosure relates to a semiconductor package.

A semiconductor package is configured to facilitate the use of an integrated circuit chip in an electronic product. For example, the semiconductor package may include a printed circuit board (PCB) and a semiconductor chip, which is mounted on the PCB and is electrically connected to the PCB using bonding wires or bumps. With development of electronics industry, many studies are being conducted to improve reliability of the semiconductor package and to reduce a size of the semiconductor package.

### SUMMARY

One or more example embodiments provide a highly-reliable semiconductor package, which is configured to reduce parasitic inductance and resistance between a circuit layer including a semiconductor chip with a transistor and a capacitor and to stably supply an electric power to the semiconductor chip.

According to an aspect of an embodiment of the inventive concept, a semiconductor package includes: a first semiconductor chip. The first semiconductor chip includes: a first semiconductor substrate with a first surface and a second surface, which are opposite to each other; a circuit layer on the first surface; a first interconnection layer on the circuit layer; a second interconnection layer on the second surface; a penetration via extending from the second surface into the first semiconductor substrate; and a capacitor extending from the second surface toward the first surface. The capacitor is spaced apart from the penetration via in a first direction that is parallel to the first surface of the first semiconductor substrate.

According to an aspect of an embodiment, a semiconductor package includes: a first semiconductor chip; and a second semiconductor chip on the first semiconductor chip. The first semiconductor chip includes: a first semiconductor substrate with a first surface and a second surface, which are opposite to each other, wherein the first surface is between the second semiconductor chip and the second surface, a signal line layer and a buried power rail on the first surface; a power distribution interconnection layer on the second surface; a penetration via extending from the power distribution interconnection layer to the buried power rail; and a capacitor provided between the first surface and the power distribution interconnection layer.

According to an aspect of an embodiment, a semiconductor package includes: a package substrate; an interposer on the package substrate; a chip stack and a chip structure provided on the interposer and spaced apart from each other in a horizontal direction; and a mold structure on a side surface of the chip stack, a side surface of the chip structure, and a top surface of the interposer. The chip structure includes: a first semiconductor chip; and a second semiconductor chip on the first semiconductor chip. The first semiconductor chip includes: a first semiconductor substrate with a first surface and a second surface, which are opposite to each other, wherein the first surface is between the second semiconductor chip and the second surface; a first interconnection layer on the first surface; a second interconnection layer on the second surface; and a capacitor between the second interconnection layer and the first semiconductor substrate. The second semiconductor chip includes: a second semiconductor substrate; and an insulating layer between the second semiconductor substrate and the first interconnection layer. The chip stack includes a plurality of semiconductor chips and a first penetration via extending into the plurality of semiconductor chips. A trench extends into the first semiconductor substrate from the second surface toward the first surface. The capacitor is provided in the trench. The insulating layer and the first interconnection layer are in contact with each other.

### BRIEF DESCRIPTION OF DRAWINGS

The above and other aspects and features will be more apparent from the following description of example embodiments, taken in conjunction with the accompanying drawings, in which:

FIG. 1 is a sectional view schematically illustrating a semiconductor package according to an example embodiment;

FIG. 2 is an enlarged view illustrating a portion ‘aa’ of FIG. 1 according to an example embodiment;

FIG. 3 is an enlarged view illustrating the portion ‘aa’ of FIG. 1 according to an example embodiment;

FIG. 4 is a sectional view schematically illustrating a semiconductor package according to an example embodiment;

FIG. 5 is an enlarged view illustrating a portion ‘bb’ of FIG. 4 according to an example embodiment;

FIGS. 6A, 7A, 7B, 8A, 9A, 10A, 11A, and 12A are sectional views illustrating a process of fabricating a semiconductor package, according to an example embodiment;

FIG. 6B is an enlarged view illustrating a portion ‘cc’ of FIG. 6A according to an example embodiment;

FIG. 7B is an enlarged view illustrating a portion ‘dd’ of FIG. 7A according to an example embodiment;

FIG. 8B is an enlarged view illustrating a portion ‘ee’ of FIG. 8A according to an example embodiment;

FIG. 9B is an enlarged view illustrating a portion ‘ff’ of FIG. 9A according to an example embodiment;

FIGS. 10B and 10C are enlarged sectional views illustrating a portion ‘gg’ of FIG. 10A, and in particular, a process of fabricating a capacitor according to an example embodiment;

FIG. 11B is an enlarged view illustrating a portion ‘hh’ of FIG. 11A according to an example embodiment;

FIG. 12B is an enlarged view illustrating a portion ‘ii’ of FIG. 12A according to an example embodiment;

FIG. 13A is a sectional view illustrating a process of fabricating a semiconductor package, according to an example embodiment; and

FIG. 13B is an enlarged view illustrating a portion ‘jj’ of FIG. 13A according to an example embodiment.

### DETAILED DESCRIPTION

Example embodiments will be described more fully with reference to the accompanying drawings, in which example embodiments are shown.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

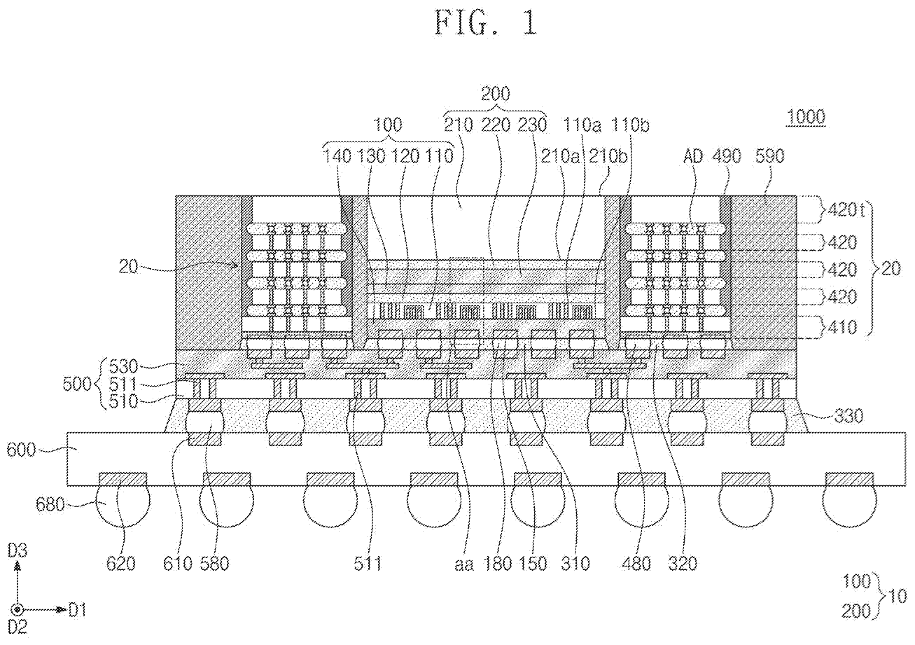

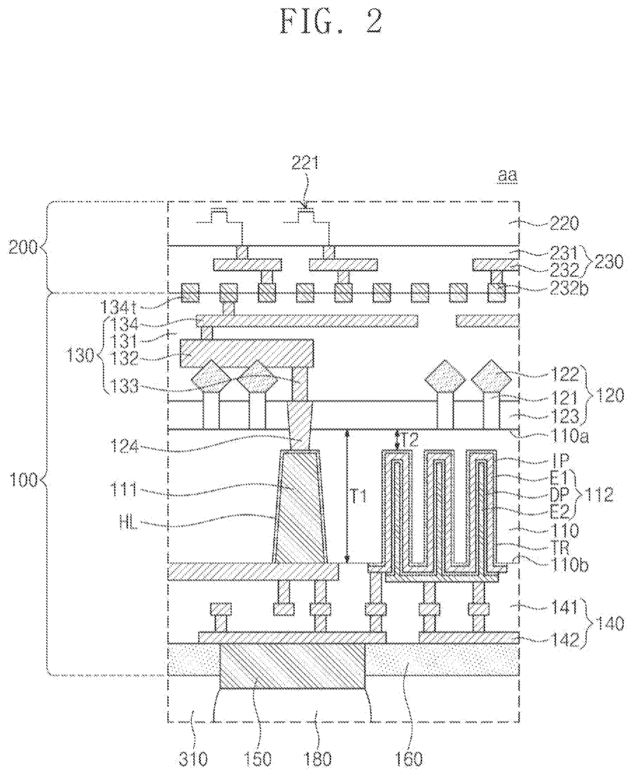

FIG. 1 is a sectional view schematically illustrating a semiconductor package according to an example embodiment. FIG. 2 is an enlarged view illustrating a portion ‘aa’ of FIG. 1.

Referring to FIGS. 1 and 2, a semiconductor package 1000 may include a package substrate 600, an interposer 500, a chip structure 10, a sub-semiconductor package 20, and a first mold structure 590.

The interposer 500 may be disposed on the package substrate 600. The chip structure 10, the sub-semiconductor package 20, and the first mold structure 590 may be disposed on the interposer 500.

The chip structure 10 may include a first semiconductor chip 100 and a second semiconductor chip 200. In an example embodiment, the chip structure 10 may be a system-on-chip (SOC).

The second semiconductor chip 200 may be disposed on the first semiconductor chip 100. The first semiconductor chip 100 and the second semiconductor chip 200 may be bonded to each other in a hybrid bonding manner, without connection terminals (e.g., solder balls, bumps, and pillars) interposed therebetween.

As shown in FIGS. 1 and 2, the first semiconductor chip 100 may include a first semiconductor substrate 110, a first circuit layer 120, a first interconnection layer 130, a penetration via 111, a capacitor 112, and a second interconnection layer 140.

The first semiconductor substrate 110 may be, for example, a silicon (Si) substrate. The first semiconductor substrate 110 may include a first surface 110a and a second surface 110b, which are opposite to each other. The second semiconductor chip 200 may be closer to the first surface 110a than to the second surface 110b. The first circuit layer 120 may be disposed on the first surface 110a of the first semiconductor substrate 110. The first surface 110a may be in contact with a bottom surface of a device isolation layer 123, which will be described below. The first surface 110a may be referred to as a front surface, and the second surface 110b may be referred to as a rear surface. The term “front surface” may indicate a surface where the first circuit layer 120 is disposed, while the term “rear surface” may indicate a surface where the first circuit layer 120 is not disposed.

The first circuit layer 120 may be disposed on the first surface 110a of the first semiconductor substrate 110. The first circuit layer 120 may indicate a layer or region where an integrated circuit (e.g., a transistor) is formed.

The first circuit layer 120 may include fins 121 and an epitaxial pattern 122. A space between the fins 121 may be filled with the device isolation layer 123. Each of the fins 121 may vertically protrude in relation to the first surface 110a of the first semiconductor substrate 110 and the device isolation layer 123. The fins 121 may be used as channel structures of fin field-effect transistors (FinFETs), but example embodiments are not limited to this example. According to example embodiments, the transistor of the first semiconductor chip 100 may be one of a single or combined FinFET, a nano-wire transistor, a nano-sheet transistor, and so on. In an example embodiment, the fins 121 may be formed of or include silicon (Si). Each of the epitaxial pattern 122 may be formed of or include a semiconductor material (e.g., silicon (Si), germanium (Ge), and silicon-germanium (SiGe)). The device isolation layer 123 may be formed of or include an insulating material. The device isolation layer 123 may be formed of or include at least one of oxide materials (e.g., silicon oxide (SiO2)).

The epitaxial pattern 122, in conjunction with an epitaxial contact 132 described below, may constitute a transistor.

A buried power rail 124 may be provided on the first semiconductor substrate 110. The buried power rail 124 may extend to penetrate the device isolation layer 123 and may extend through the first surface 110a into an upper portion of the first semiconductor substrate 110. In an example embodiment, the buried power rail 124 may include a protruding portion that extends to a level higher than a top surface of the device isolation layer 123. In an example embodiment, a top surface of the buried power rail 124 may be placed at a level lower than a bottom surface of the device isolation layer 123. The buried power rail 124 may be formed of or include at least one of metallic materials (e.g., copper (Cu), cobalt (Co), tungsten (W), ruthenium (Ru), or alloys thereof).

The first interconnection layer 130 may be disposed on the first circuit layer 120. The first interconnection layer 130 may include a first insulating layer 131 and the epitaxial contact 132, a vertical contact 133, and first interconnection lines 134, which are provided in the first insulating layer 131.

The first insulating layer 131 may be formed of or include an insulating material, such as an oxide material (e.g., SiO2). There may be no observable interface between the first insulating layer 131 and the device isolation layer 123.

The epitaxial contact 132 may be disposed on the epitaxial pattern 122. The epitaxial contact 132 may be a metal layer that extends in a first direction D1, which is parallel to a first surface 100a of the first semiconductor substrate 110, and is in contact with the epitaxial pattern 122. A second direction D2 may be parallel to the first surface 100a and perpendicular to the first direction D1. A third direction D3 may be perpendicular to the first surface 100a.

The vertical contact 133 may be disposed between the epitaxial contact 132 and the buried power rail 124 to connect them to each other. The vertical contact 133 may be a via plug, which extends from the epitaxial contact 132 in the second direction D2 that is perpendicular to the first surface 100a of the first semiconductor substrate 110.

The first interconnection lines 134 may be disposed on the epitaxial contact 132. The first interconnection lines 134 may be formed of or include at least one of metallic materials (e.g., copper and aluminum). The first interconnection lines 134 may be used as a part of a routing structure for signal transmission, and may be referred to as signal lines 134.

The epitaxial pattern 122 may include a power tapping epitaxial pattern, which is used as an interconnection element for the supply of electric power, and a non-power tapping epitaxial pattern, which is not used for the supply of electric power. The signal lines 134 may be connected to the non-power tapping epitaxial pattern and may be used as a routing structure for the signal transmission between the transistors. A power distribution line 142 described below may be connected to the power tapping epitaxial pattern but may not be connected to the signal lines 134.

The penetration via 111 may extend from the second surface 110b of the first semiconductor substrate 110 toward the first surface 110a in the third direction D3. The first semiconductor substrate 110 may include a plurality of penetration holes HL, which are formed to have a specific depth in the third direction D3. The penetration via 111 may be disposed in the penetration hole HL. The penetration via 111 may include a barrier pattern and a conductive pattern on the barrier pattern. The barrier pattern may be formed of or include at least one of tungsten nitride (WN), titanium nitride (TiN), titanium silicon nitride (TiSN), tungsten silicon nitride (WSiN), or ruthenium titanium nitride (RuTiN). The conductive pattern may be formed of or include at least one of tungsten (W), copper (Cu), polysilicon, or aluminum (Al). The penetration via 111 may be in contact with the buried power rail 124.

The capacitor 112 may be spaced apart from the penetration via 111 in the first direction D1 and/or the second direction D2. The first semiconductor substrate 110 may include at least one trench TR. The trench TR may be formed to have a specific depth in the third direction D3. The capacitor 112 may be disposed in the trench TR. The capacitor 112 may include a first electrode El, a second electrode E2, and a dielectric pattern DP interposed therebetween. In an example embodiment, the first electrode El and the second electrode E2 may be formed of or include polysilicon. The dielectric pattern DP may be formed of or include at least one of silicon oxide (SiO₂) or silicon nitride (Si₃N₄). An insulating pattern IP may be interposed between an inner surface of the trench TR and the capacitor 112. The insulating pattern IP may be formed of or include at least one of silicon oxide (SiO₂) or silicon nitride (Si₃N₄). In an example embodiment, the first electrode E1 and the second electrode E2 may be formed of or include at least one of metallic materials.

A first distance Tl between the first and second surfaces 110a and 110b of the first semiconductor substrate 110 may be larger than a second distance T2 between the capacitor 112 and the first surface 110a. For example, the second distance T2 may be the shortest distance between the capacitor 112 and the first surface 110a.

The second interconnection layer 140 may be disposed on the second surface 110b of the first semiconductor substrate 110. The second interconnection layer 140 may include a second insulating layer 141 and second interconnection lines 142 in the second insulating layer 141. The second insulating layer 141 may be formed of or include an insulating material (e.g., silicon oxide). The second interconnection lines 142 may be formed of or include a metallic material (e.g., copper, aluminum). The second interconnection lines 142 may be referred to as power distribution lines or a power distribution network (PDN). The power distribution lines 142 may be connected to the capacitor 112 and the penetration via 111. In detail, the power distribution lines 142 may be connected to two electrodes El and E2 of the capacitor 112.

Chip pads 150 and a protection layer 160 may be disposed on the second interconnection layer 140. The chip pads 150 may be formed of or include aluminum or copper. The protection layer 160 may be formed of or include an insulating material (e.g., silicon nitride (Si₃N₄)). First connection terminals 180 may be disposed on the chip pads 150, respectively. The first connection terminal 180 may include solder balls, bumps, pillars, or the like. A first under fill pattern 310 may be provided to cover a side surface of the first connection terminal 180. The first under fill pattern 310 may be formed of or include an insulating material (e.g., an epoxy resin).

The second semiconductor chip 200 may include a second semiconductor substrate 210, a second circuit layer 220, and a third interconnection layer 230.

The second semiconductor substrate 210 may include a third surface 210a and a fourth surface 210b, which are opposite to each other. The third surface 210a may be closer to the first semiconductor chip 100 than the fourth surface 210b. The fourth surface 210b may be exposed to the outside of the first mold structure 590. In an example embodiment, the second semiconductor substrate 210 may be formed of or include silicon, and a thickness of the second semiconductor substrate 210 may be larger than a thickness of the first semiconductor substrate 110.

The second circuit layer 220 may be disposed on the third surface 210a of the second semiconductor substrate 210 and may include an integrated circuit 221 (e.g., a transistor). For example, the second semiconductor chip 200 may be a memory chip (e.g., a static random-access memory (SRAM) chip).

The third interconnection layer 230 may be disposed on the second circuit layer 220. The third interconnection layer 230 may include a third insulating layer 231 and third interconnection lines 232. The third interconnection lines 232 may be provided in the third insulating layer 231. The third interconnection lines 232 may be formed of or include at least one of metallic materials (e.g., aluminum or copper). The third insulating layer 231 may be formed of or include, for example, silicon oxide.

The lowermost one of the third interconnection lines 232 (hereinafter, a third interconnection lines 232b) may be in contact with the uppermost one of the first interconnection lines 134 (hereinafter, a first interconnection lines 134t). In an example embodiment, there may be no observable interface between the third interconnection lines 232b and the first interconnection lines 134t, which are in contact with each other. For example, solder balls, bumps, pillars, and so on may not be interposed between the third interconnection lines 232b and the first interconnection lines 134t. The first insulating layer 131 and the third insulating layer 231 may be in contact with each other. In an example embodiment, there may be no observable interface between the first insulating layer 131 and the third insulating layer 231.

The sub-semiconductor package 20 may be disposed to be spaced apart from the chip structure 10 in the first direction D1 and/or the second direction D2. The sub-semiconductor package 20 may be referred to as a chip stack 20 or a high bandwidth memory (HBM) 20. The sub-semiconductor package 20 may include a third semiconductor chip 410 and fourth semiconductor chips 420 and 420t, and a second mold structure 490, which are disposed on the third semiconductor chip 410. The third semiconductor chip 410 may be referred to as a base chip 410, and the fourth semiconductor chips 420 and 420t may be referred to as memory chips 420 and 420t.

The base chip 410 may be a logic chip. As an example, the base chip 410 may be a memory controller.

The memory chips 420 and 420t may be stacked on the base chip 410 in the third direction D3. The memory chips 420 and 420t may be the same kind of semiconductor chips and may include the same circuit. The memory chips 420 and 420t may be dynamic random access memory (DRAM) chips or NAND flash memory chips.

Each of the base and memory chips 410, 420, and 420t may include a circuit layer. The base chip 410 and the memory chips 420 may include penetration vias. A memory chip 420t, which is the uppermost one of the memory chips 420 and 420t, may not include penetration vias provided therein. In an example embodiment, the uppermost memory chip 420t may include penetration vias. The penetration vias of the base chip 410 may be connected to the penetration vias of the memory chip 420 adjacent thereto through micro-bumps. The penetration vias of adjacent ones of the memory chips 420 may be connected to each other through micro-bumps.

Adhesive layers AD may be interposed between the base chip 410 and the memory chip 420, which are adjacent to each other, and between the memory chips 420, which are adjacent to each other. In an example embodiment, the adhesive layers AD may be a polymer-containing non-conductive film (NCF).

The second mold structure 490 may cover a top surface of the base chip 410, side surfaces of the memory chips 420 and 420t, and side surfaces of the adhesive layers AD. A top surface of the uppermost memory chip 420t may be exposed to the outside of the second mold structure 490. For example, the top surface of the uppermost memory chip 420t may correspond to a top surface of the semiconductor package 1000.

Second connection terminals 480 may be disposed below the base chip 410. The second connection terminal 480 may include solder balls, bumps, pillars, or the like. A second under fill pattern 312 may cover side surfaces of the second connection terminals 480. The second under fill pattern 312 may be formed of or include an insulating material (e.g., an epoxy resin).

In an example embodiment, the package substrate 600 may be a printed circuit board (PCB). The package substrate 600 may include upper pads 610 and lower pads 620, which are respectively provided on top and bottom surfaces thereof or in upper or lower portions thereof. An outer connection terminal 680 may be provided on each of the lower pads 620 and may be connected to an external board (e.g., a motherboard). The outer connection terminal 680 may be formed of or include at least one of conductive materials, such as soldering materials.

In an example embodiment, the interposer 500 may be a silicon interposer. The interposer 500 may include a supporting substrate 510, a fourth interconnection layer 530 on the supporting substrate, and a plurality of penetration vias 511 penetrating the supporting substrate 510. The supporting substrate 510 may be, for example, a silicon substrate. The interposer 500 may connect the chip structure 10 to the sub-semiconductor package 20. Third connection terminals 580 may be disposed between the interposer 500 and the package substrate 600. Third connection terminal 580 may be formed of or include at least one of conductive materials (e.g., soldering materials). A third under fill pattern 330 may be disposed on the package substrate 600 to cover side surfaces of the third connection terminals 580. The third under fill pattern 330 may be formed of or include an insulating material (e.g., epoxy resin).

The first mold structure 590 and the second mold structure 490 may be formed of or include an insulating material (e.g., an epoxy molding compound (EMC)).

According to an example embodiment, the first semiconductor chip 100 may have a backside power distribution network (BSPDN) structure and may have a structure, in which the capacitor 112 is placed in the first semiconductor substrate 110.

In a comparative example, the capacitor may be provided outside the first semiconductor chip 100, rather than inside the first semiconductor chip 100. Furthermore, all the signal lines 134 and the power distribution lines 142 may be provided as a single interconnection layer disposed on the first circuit layer 120. For example, all the signal lines 134 and the power distribution lines 142 may be disposed on the first surface 110a of the first semiconductor substrate 110. To suppress an interference or disturbance issue between the signal lines 134 and the power distribution lines 142, the interconnection layer with the signal lines 134 and the power distribution lines 142 should be formed to have a large thickness (e.g., larger than a sum of thicknesses of the first and second interconnection layers 130 and 140 according to an example embodiment). For example, in the comparative example, a total length of interconnection elements connecting the first circuit layer 120 to the capacitor may be equal to or larger than 10 mm.

According to an example embodiment, the capacitor 112 may be disposed adjacent to the first circuit layer 120. The power distribution lines 142, the penetration via 111, and the buried power rail 124 may be used to connect the capacitor 112 to the first circuit layer 120, and a total length of an interconnection path, which is formed by the power distribution lines 142, the penetration via 111, and the buried power rail 124, may be less than 10 um.

The capacitor 112 may be used to reduce noise issues (e.g., parasitic inductance and resistance), which may be produced between conduction paths connecting the transistor, the signal lines 134, and the power distribution lines 142. In the first semiconductor chip 100 according to an example embodiment, because the capacitor 112 is disposed on the rear surface 110b of the first semiconductor substrate 110, a distance between the transistor of the first circuit layer 120 and the capacitor 112 may be reduced, and thus, it may be possible to effectively reduce the noise issues. Furthermore, because the capacitor 112 is connected to the power distribution lines 142, it may be possible to stably supply an electric power to the chip structure 10. In an example embodiment, the capacitor 112 may be connected to the metal layers on the first surface 110a through the penetration via 111.

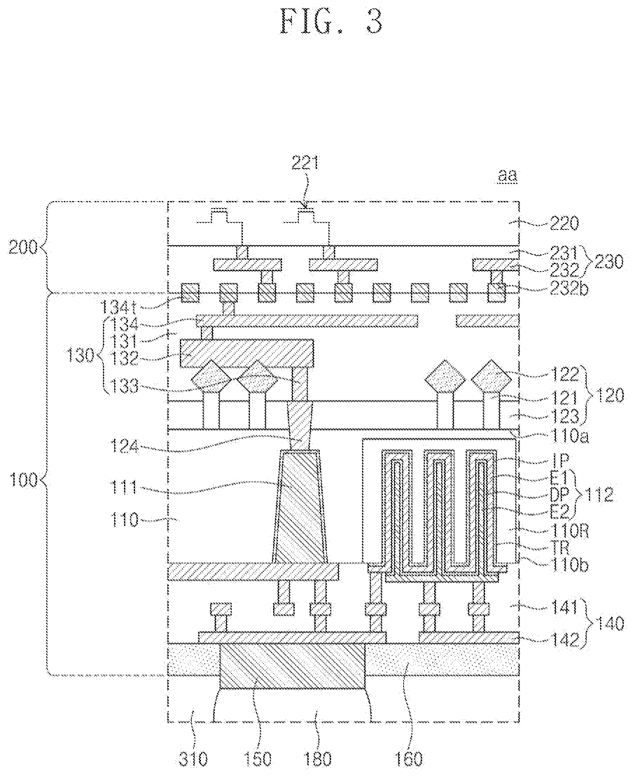

FIG. 3 is an enlarged view illustrating the portion ‘aa’ of FIG. 1. Except for features to be described below, the package may have substantially the same features as those described with reference to FIGS. 1 and 2, and thus, an overlapping description thereof may be omitted.

Referring to FIGS. 1 and 3, the first semiconductor substrate 110 may include a doped region 110R. The doped region 110R may have a conductivity type different from the first semiconductor substrate 110. For example, in the case where the first semiconductor substrate 110 have a conductivity type of n−, and the doped region 110R may have a conductivity type of p++.

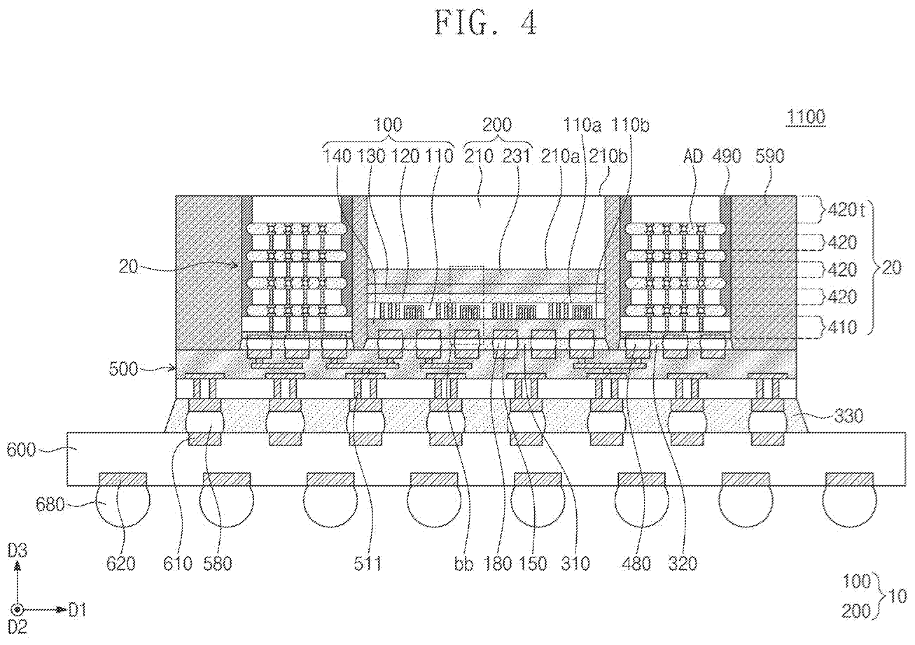

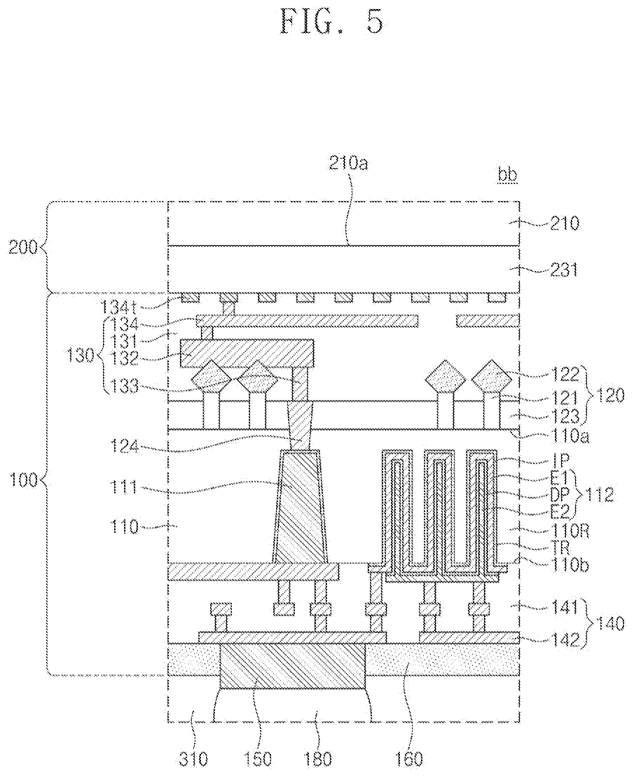

FIG. 4 is a sectional view illustrating a semiconductor package according to an example embodiment. FIG. 5 is an enlarged view illustrating a portion ‘bb’ of FIG. 4. Except for features to be described below, the package may have substantially the same features as those described with reference to FIGS. 1 and 2, and thus, an overlapping description thereof may be omitted.

Referring to FIGS. 4 and 5, the second semiconductor chip 200 of a semiconductor package 1100 may be a dummy chip. In this regard, the second semiconductor chip 200 may not include the second circuit layer 220, and any integrated circuit may not be disposed on the second semiconductor substrate 210.

The third surface 210a of the second semiconductor substrate 210 may be in contact with the third insulating layer 231. The third interconnection lines 232 may not be provided in the third insulating layer 231. In an example embodiment, the third interconnection lines 232 may be provided in the third insulating layer 231, as shown in FIGS. 1 and 2.

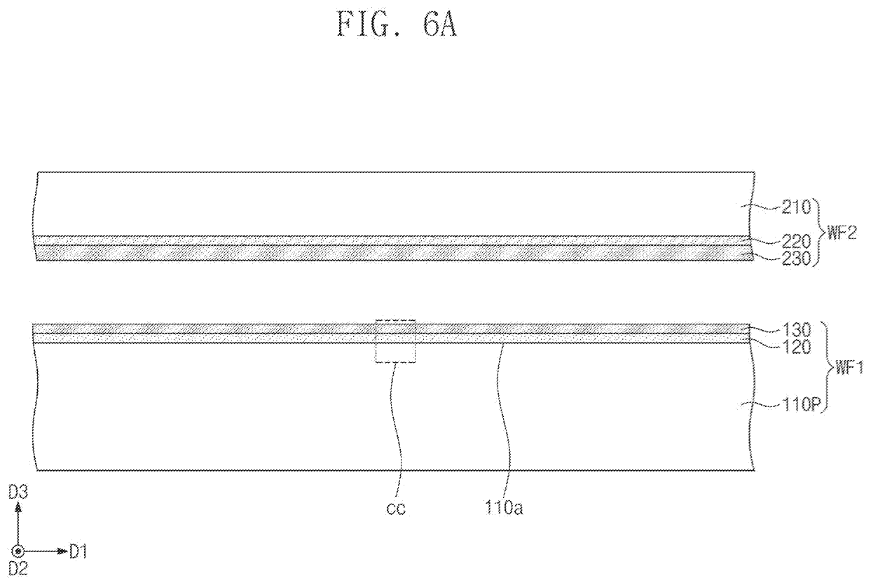

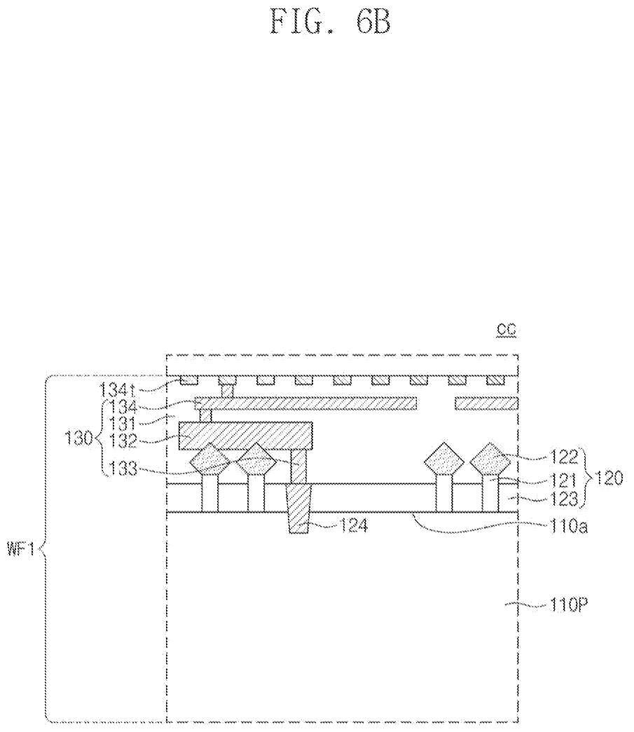

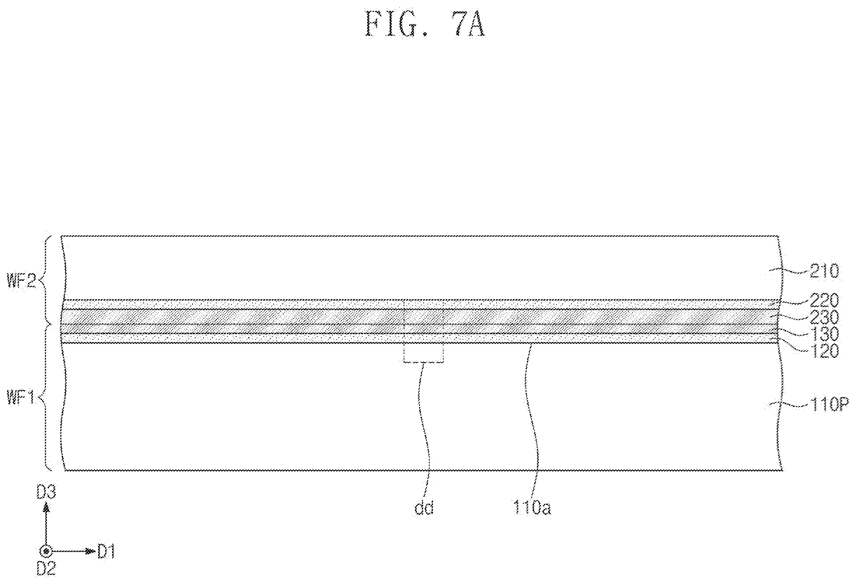

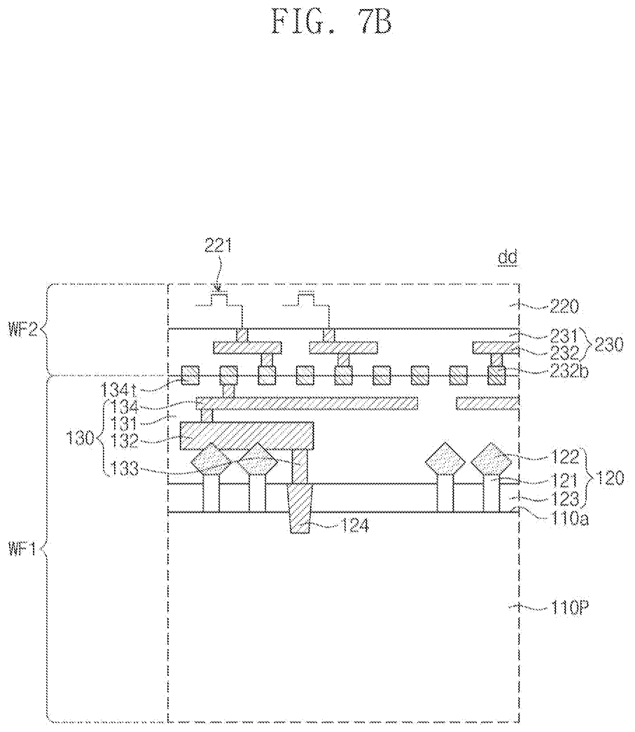

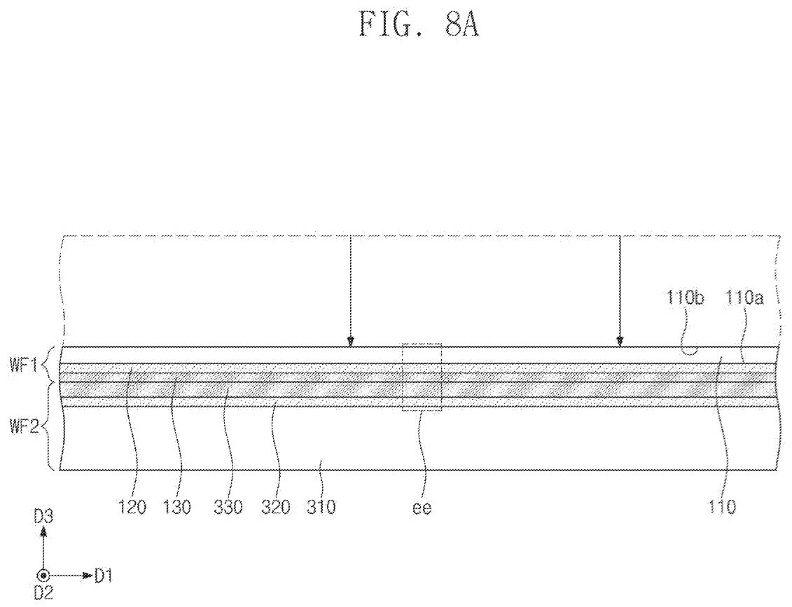

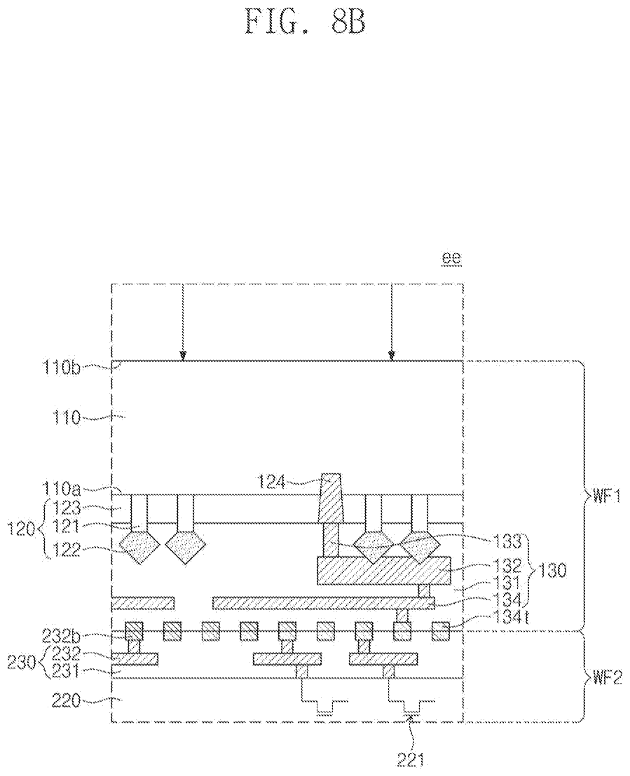

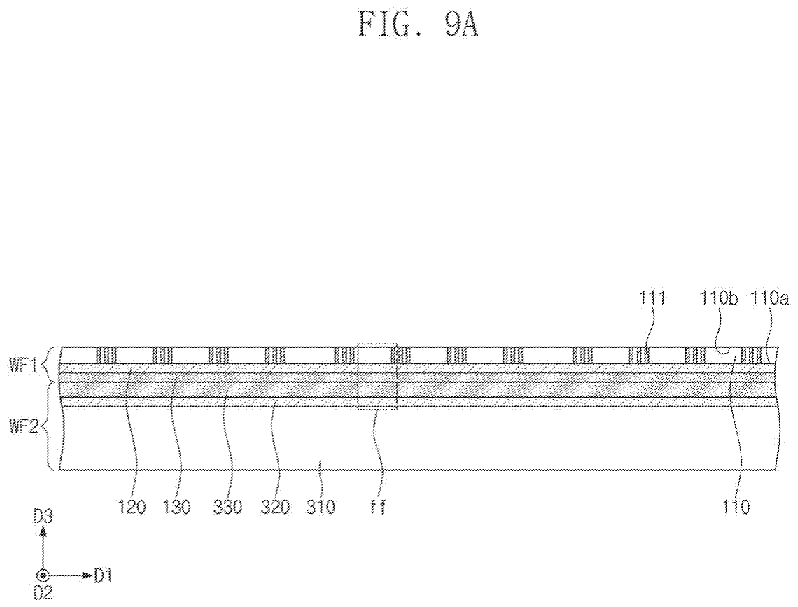

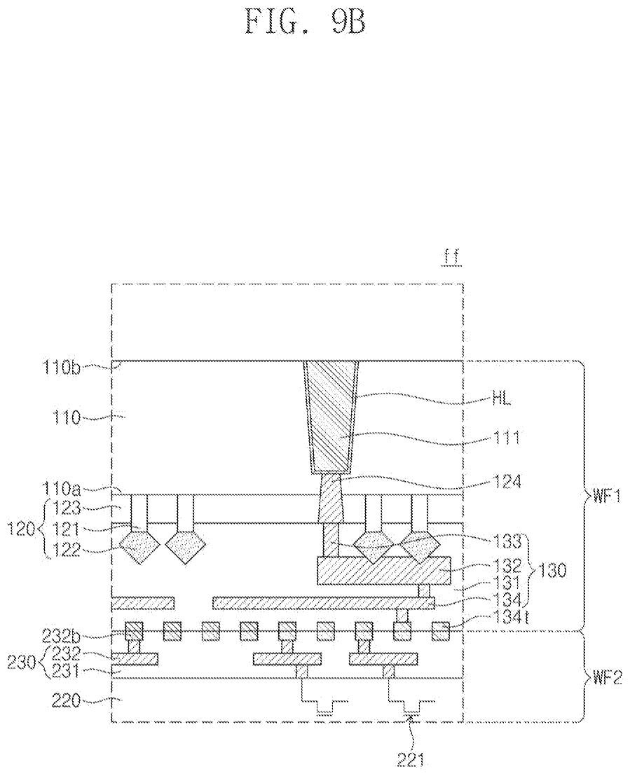

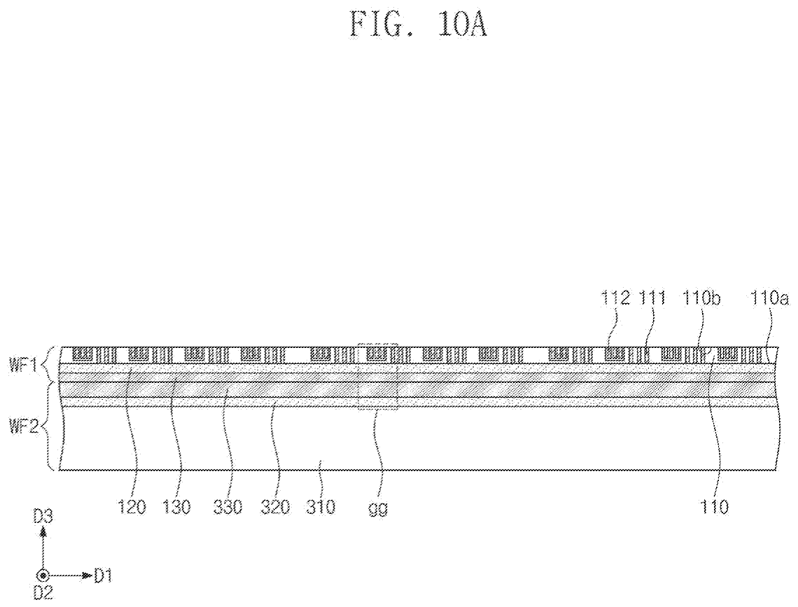

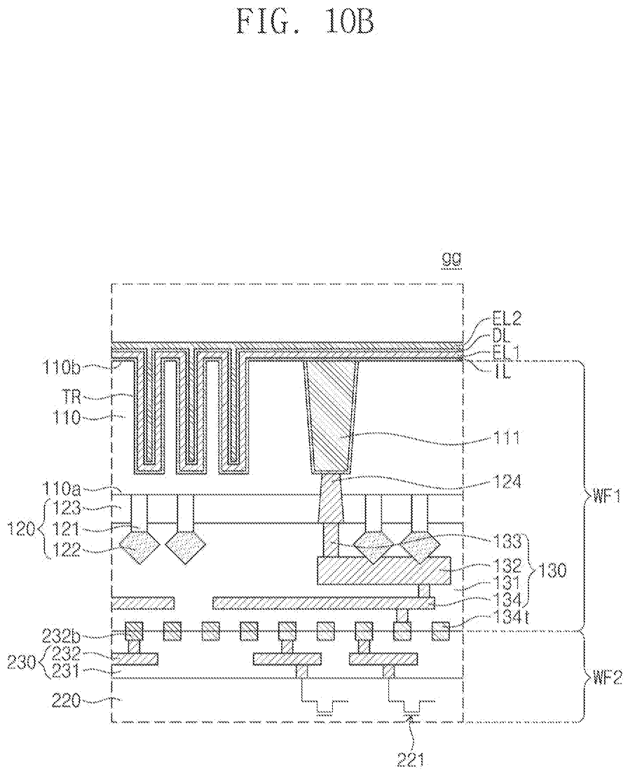

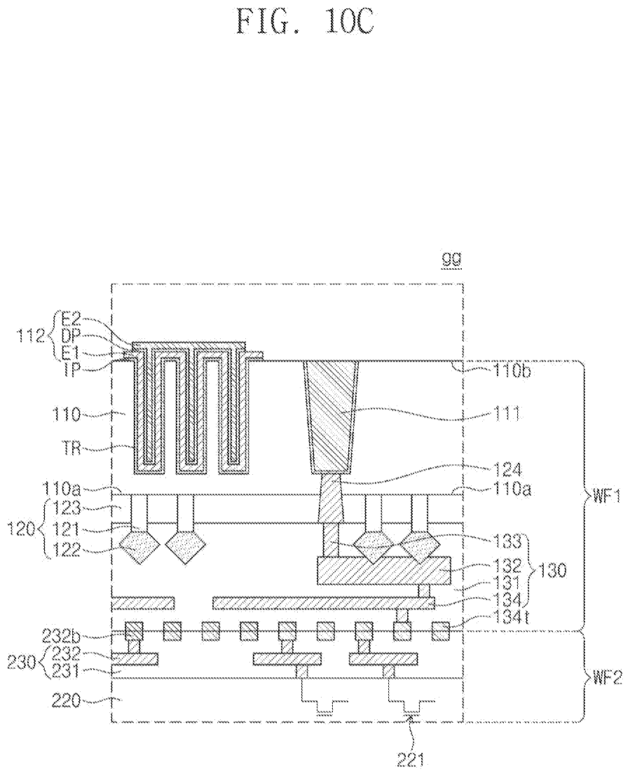

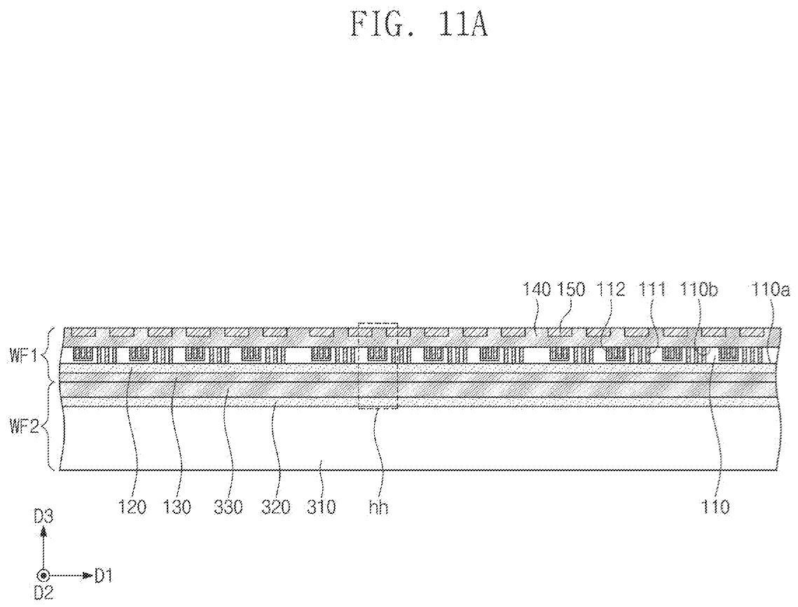

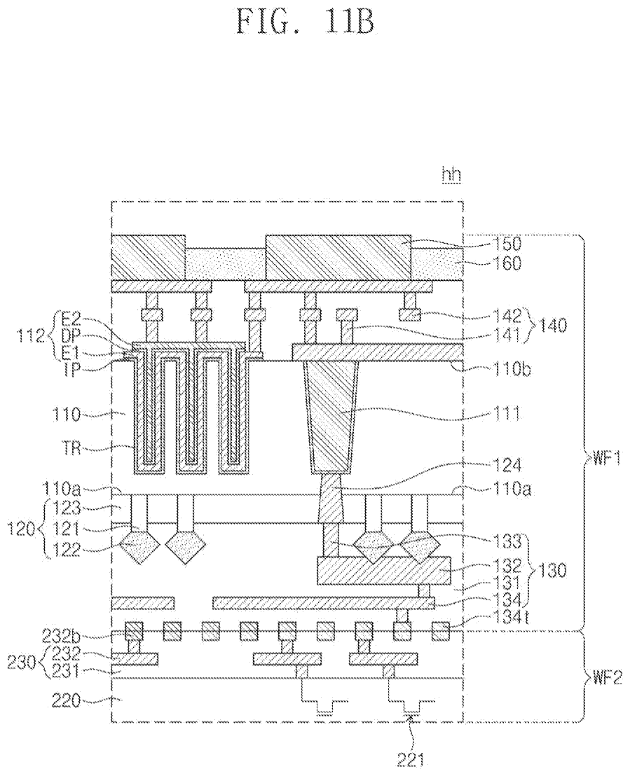

FIGS. 6A, 7A, 7B, 8A, 9A, 10A, 11A, and 12A are sectional views illustrating a process of fabricating a semiconductor package, according to an example embodiment. FIG. 6B is an enlarged view illustrating a portion ‘cc’ of FIG. 6A. FIG. 7B is an enlarged view illustrating a portion ‘dd’ of FIG. 7A. FIG. 8B is an enlarged view illustrating a portion ‘ee’ of FIG. 8A. FIG. 9B is an enlarged view illustrating a portion ‘ff’ of FIG. 9A. FIGS. 10B and 10C are enlarged sectional views illustrating a portion ‘gg’ of FIG. 10A, and in particular, a process of fabricating a capacitor. FIG. 11B is an enlarged view illustrating a portion ‘hh’ of FIG. 11A.

Referring to FIGS. 6A and 6B, a first wafer WF1 and a second wafer WF2 may be provided. The first wafer WF1 may include a first preliminary semiconductor substrate 110P, the first circuit layer 120, and the first interconnection layer 130.

In detail, the fins 121 may be formed by patterning a surface of the preliminary semiconductor substrate 110P. Each of the fins 121 may be used as a current channel of a transistor. Although the fins 121 are illustrated to have the fin structure of FinFET, each of the fins 121 may include a variety of elements (such as nano-wires or nano-sheets) for a nano-wire transistor or a nano-sheet transistor, or any combination of these structures. In an example embodiment, a space between the fins 121 may be filled with the device isolation layer 123, which is formed of or includes silicon oxide (SiO2). The buried power rail 124 may be formed to penetrate the device isolation layer 123, and in an example embodiment, may extend into the preliminary semiconductor substrate 110P.

The epitaxial patterns 122 may be formed on the fins 121. In an example embodiment, the epitaxial patterns 122 may be used as active regions of the transistor including source/drain regions and may be formed of or include silicon (Si). The vertical contact 133 and the epitaxial contact 132 may be formed simultaneously or sequentially. Next, the first interconnection lines 134 may be formed on the epitaxial contact 132.

The second wafer WF2 may include the second semiconductor substrate 210, the second circuit layer 220, and the third interconnection layer 230.

Referring to FIGS. 7A and 7B, a wafer-to-wafer bonding process may be performed. As a result, the second wafer WF2 may be in contact with the first wafer WF1.

The second wafer WF2 may be directly bonded to the first wafer WF1 through a direct bonding process, without using any adhesive layer. During the bonding process, the first and second wafers WF1 and WF2 may be exposed to a high heat environment. The first interconnection layer 130 and the third interconnection layer 230 may be in contact with each other. In detail, the first interconnection lines 134t and the third interconnection lines 232b may be disposed to be in contact with each other, and the first insulating layer 131 and the third insulating layer 231 may be disposed to be in contact with each other.

Referring to FIGS. 8A and 8B, the first and second wafers WF1 and WF2 may be inverted, as shown. A thinning process, which includes a chemical-mechanical polishing (CMP) process, a grinding process, or a dry etching process, may be performed to reduce a thickness of the preliminary semiconductor substrate 110P of the first wafer WF1. As a result of the thinning process, the first semiconductor substrate 110 may be formed.

Referring to FIGS. 9A and 9B, the penetration hole HL may be formed in the first semiconductor substrate 110 to expose the buried power rail 124. Next, the penetration via 111 may be formed on the buried power rail 124 to be in contact with the buried power rail 124. The formation of the penetration via 111 may include forming a barrier layer, forming a conductive layer on the barrier layer, and patterning the barrier layer and the conductive layer.

Referring to FIGS. 10A and 10B, at least one trench TR, which is recessed from the second surface 110b toward the first surface 110a, may be formed in the first semiconductor substrate 110. Thereafter, an insulating layer IL, a first conductive layer EL1, a dielectric layer DL, and a second conductive layer EL2 may be sequentially formed to fill the trench TR. Each of the insulating layer IL, the first conductive layer EL1, the dielectric layer DL, and the second conductive layer EL2 may be formed by a deposition method, such as chemical vapor deposition (CVD), physical vapor deposition (PVD), and atomic layer deposition (ALD) methods.

Referring to FIGS. 10A and 10C, the insulating pattern IP, the first electrode E1, the dielectric pattern DP, and the second electrode E2 may be formed by patterning the insulating layer IL, the first conductive layer EL1, the dielectric layer DL, and the second conductive layer EL2, respectively. The first electrode El, the dielectric pattern DP, and the second electrode E2 may constitute the capacitor 112. In an example embodiment, the capacitor 112 may be formed, and then, the penetration via 111 may be formed.

Referring to FIGS. 11A and 11B, the second interconnection layer 140 may be formed on the second surface 110b of the first semiconductor substrate 110. The second interconnection lines 142 may be connected to the penetration via 111 and the capacitor 112. The protection layer 160 and the chip pad 150 may be formed on the second interconnection layer 140.

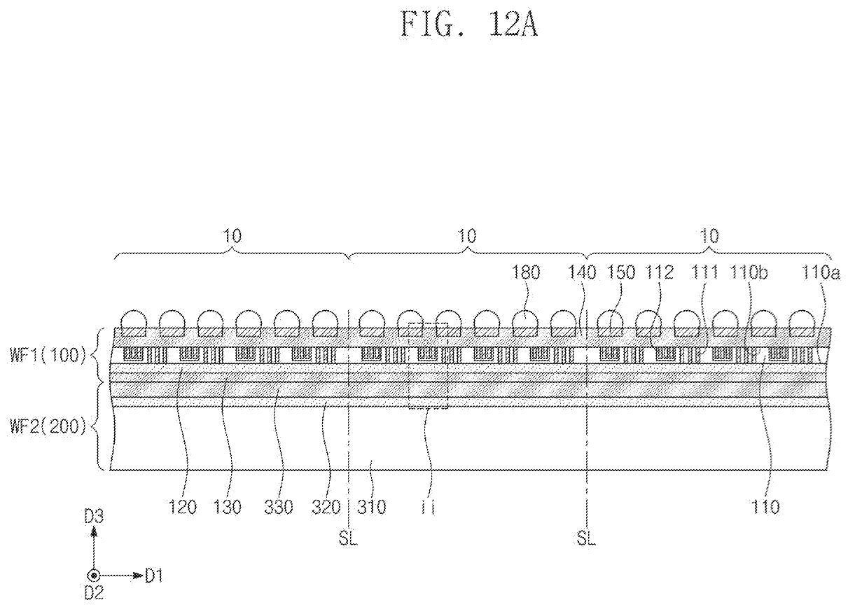

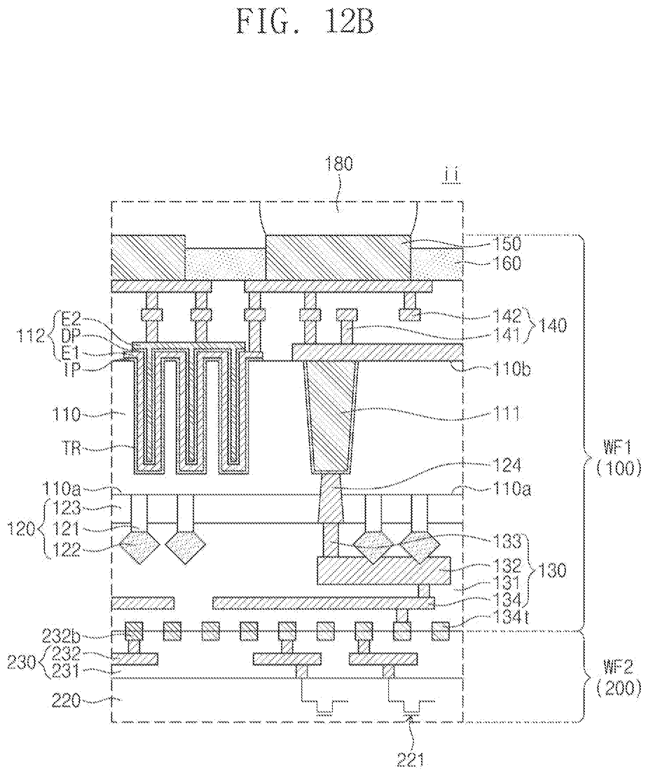

Referring to FIGS. 12A and 12B, an outer connection terminal may be formed on the chip pad 150. Next, a sawing process may be performed along a sawing line SL. As a result of the sawing process, the chip structure 10 including the first and second semiconductor chips 100 and 200 may be formed.

Referring back to FIG. 1, a chip assembly process or the like may be performed to the interposer 500, the chip structure 10, and the sub-semiconductor package 20 on a package substrate 700 and to form the first mold structure 590, and in this case, the semiconductor package 1000 may be formed.

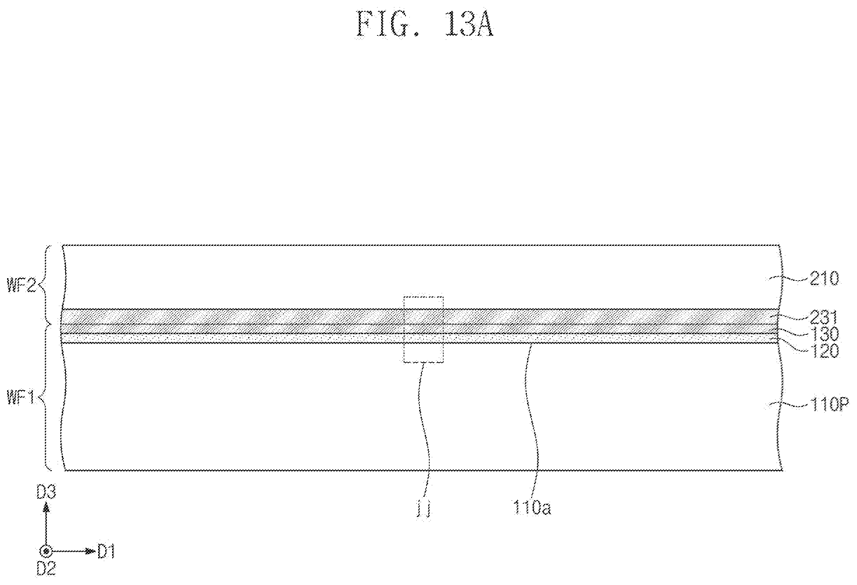

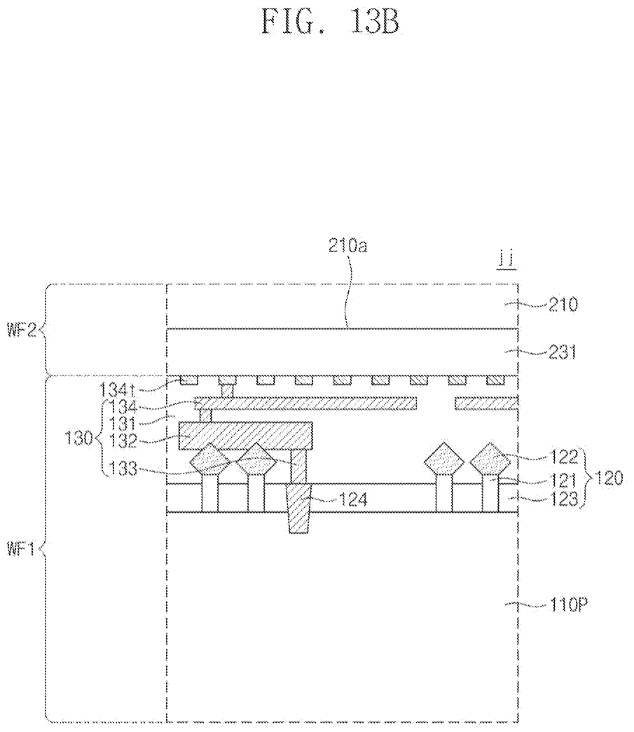

FIG. 13A is a sectional view illustrating a process of fabricating a semiconductor package, according to an example embodiment. FIG. 13B is an enlarged view illustrating a portion ‘jj’ of FIG. 13A.

FIG. 13A is a sectional view illustrating a process of fabricating a semiconductor package, according to an example embodiment. FIG. 13B is an enlarged view illustrating a portion ‘jj’ of FIG. 13A.

Referring to FIG. 13A, the second wafer WF2 may be provided to include the second semiconductor substrate 210 and the third insulating layer 231, which are in direct contact with each other. In this regard, the second wafer WF2 may not include the second circuit layer 220. The third insulating layer 231 may be in contact with the first insulating layer 131, as shown in FIGS. 13A and 13B. In an example embodiment, the third interconnection lines 232 may be disposed in the third insulating layer 231. The subsequent steps of the fabrication process may be performed in substantially the same manner as that described with reference to FIGS. 6A to 12A. In this case, the semiconductor package may be formed to have substantially the same structure as the semiconductor package 1100 of FIG. 4.

According to an example embodiment, a semiconductor package may include a semiconductor chip, in which a capacitor and a power distribution layer is disposed on a rear surface of a semiconductor substrate and a circuit layer is disposed on a front surface of the semiconductor substrate. In this case, it may be possible to reduce a distance between a capacitor and a transistor of a circuit layer in the semiconductor chip and to stably supply an electric power to the semiconductor chip. As a result, the reliability of the semiconductor package may be improved.

While aspects of example embodiments have been particularly shown and described, it will be understood by one of ordinary skill in the art that variations in form and detail may be made therein without departing from the spirit and scope of the attached claims.

What is claimed is:

1. A semiconductor package, comprising a first semiconductor chip,
wherein the first semiconductor chip comprises:
a first semiconductor substrate comprising a first surface and a second surface, which are opposite to each other;
a circuit layer on the first surface;
a first interconnection layer on the circuit layer;
a second interconnection layer on the second surface;
a penetration via extending from the second surface into the first semiconductor substrate; and
a capacitor extending from the second surface toward the first surface, and
wherein the capacitor is spaced apart from the penetration via in a first direction that is parallel to the first surface of the first semiconductor substrate.

2. The semiconductor package of claim 1, wherein the capacitor is spaced apart from the first surface.

3. The semiconductor package of claim 1, wherein a first distance between the first surface and the second surface is larger than a second distance between the capacitor and the first surface.

4. The semiconductor package of claim 1, wherein the first interconnection layer comprises signal lines, and
wherein the second interconnection layer comprises power distribution lines.

5. The semiconductor package of claim 1, further comprising a second semiconductor chip on the first semiconductor chip,
wherein the first semiconductor chip is a logic chip, and
wherein the second semiconductor chip is a dummy chip or a memory chip.

6. The semiconductor package of claim 5, wherein the first surface is between the second semiconductor chip and the second surface,
wherein the first interconnection layer comprises first interconnection lines,
wherein the second semiconductor chip comprises:
a second semiconductor substrate; and
a third interconnection layer on the second semiconductor substrate,
wherein the third interconnection layer comprises second interconnection lines, and
wherein an uppermost one of the first interconnection lines and a lowermost one of the second interconnection lines are in contact with each other.

7. The semiconductor package of claim 6, wherein the first interconnection layer further comprises a first insulating layer on the first interconnection lines,
wherein the third interconnection layer further comprises a second insulating layer on the second interconnection lines, and
wherein the first insulating layer and the second insulating layer are in contact with each other.

8. The semiconductor package of claim 7, wherein each of the first insulating layer and the second insulating layer comprises silicon oxide (SiO2).

9. The semiconductor package of claim 1, wherein the capacitor comprises:
a first electrode;
a second electrode on the first electrode; and
a dielectric pattern between the first electrode and the second electrode, and wherein each of the first electrode and the second electrode comprises poly silicon.

10. The semiconductor package of claim 1, wherein the second interconnection layer comprises power distribution lines, and
wherein the power distribution lines are connected to the capacitor.

11. The semiconductor package of claim 1, wherein a trench extends into the first semiconductor substrate from the second surface toward the first surface, and
wherein the capacitor is provided in the trench.

12. The semiconductor package of claim 1, wherein the first semiconductor substrate is doped to have a first conductivity type,
wherein the first semiconductor substrate comprises a doped region which has a second conductivity type different from the first conductivity type, and
wherein the capacitor is provided in the doped region.

13. A semiconductor package, comprising:
a first semiconductor chip; and
a second semiconductor chip on the first semiconductor chip,
wherein the first semiconductor chip comprises:
a first semiconductor substrate comprising a first surface and a second surface, which are opposite to each other, wherein the first surface is between the second semiconductor chip and the second surface,
a signal line layer and a buried power rail on the first surface;
a power distribution interconnection layer on the second surface;
a penetration via extending from the power distribution interconnection layer to the buried power rail; and
a capacitor provided between the first surface and the power distribution interconnection layer.

14. The semiconductor package of claim 13, wherein the first semiconductor chip and the second semiconductor chip are bonded to each other in a hybrid bonding manner.

15. The semiconductor package of claim 13, wherein the first semiconductor chip is a logic chip, and
wherein the second semiconductor chip is a memory chip or a dummy chip.

16. The semiconductor package of claim 13, wherein the power distribution interconnection layer comprises power distribution lines, and
wherein the power distribution lines are connected to the capacitor.

17. A semiconductor package, comprising:
a package substrate;
an interposer on the package substrate;
a chip stack and a chip structure provided on the interposer and spaced apart from each other in a horizontal direction; and
a mold structure on a side surface of the chip stack, a side surface of the chip structure, and a top surface of the interposer,
wherein the chip structure comprises:
a first semiconductor chip; and
a second semiconductor chip on the first semiconductor chip,
wherein the first semiconductor chip comprises:
a first semiconductor substrate comprising a first surface and a second surface, which are opposite to each other, wherein the first surface is between the second semiconductor chip and the second surface;
a first interconnection layer on the first surface;
a second interconnection layer on the second surface; and
a capacitor between the second interconnection layer and the first semiconductor substrate,
wherein the second semiconductor chip comprises:
a second semiconductor substrate; and
an insulating layer between the second semiconductor substrate and the first interconnection layer,
wherein the chip stack comprises a plurality of semiconductor chips and a first penetration via extending into the plurality of semiconductor chips,
wherein a trench extends into the first semiconductor substrate from the second surface toward the first surface,
wherein the capacitor is provided in the trench, and
wherein the insulating layer and the first interconnection layer are in contact with each other.

18. The semiconductor package of claim 17, wherein the first semiconductor chip further comprises a second penetration via extending from the second interconnection layer into the first semiconductor substrate,
wherein the second interconnection layer comprises power distribution lines, and
wherein the power distribution lines are connected to the capacitor and the penetration via.

19. The semiconductor package of claim 17, further comprising an insulating pattern provided between the capacitor and the trench,
wherein the capacitor comprises:
a first electrode on the insulating pattern;
a second electrode on the first electrode; and
a dielectric pattern between the first electrode and the second electrode.

20. The semiconductor package of claim 18, wherein a thickness of the second semiconductor substrate is larger than a thickness of the first semiconductor substrate.
